(19) United States
(12) Patent Application Publication
(10) Pub. No.: US 2024/0091828 A1
(43) Pub. Date: Mar. 21, 2024

(54) CLEANING APPARATUS FOR WAFER STORAGE CONTAINER

(71) Applicant: SHIBAURA MECHATRONICS CORPORATION, Kanagawa (JP)

(72) Inventors: Junji ISHIHARA, Kanagawa (JP); Katsuhiro YAMAZAKI, Kanagawa (JP); Hisaaki MIYASAKO, Kanagawa (JP); Yukinobu NISHIBE, Kanagawa (JP)

(21) Appl. No.: 18/369,002

(22) Filed: Sep. 15, 2023

(30) Foreign Application Priority Data
Sep. 20, 2022 (JP) 2022-148809
Jul. 31, 2023 (JP) 2023-124167

(51) Int. Cl. B08B 9/08; B08B 9/20; B08B 9/46

(52) U.S. Cl. CPC B08B 9/0813; B08B 9/20; B08B 9/46; B08B 2209/08

(57) ABSTRACT

According to an embodiment of the present disclosure, the cleaning apparatus includes a cleaning tank body having a body opening and a cleaning space; a lid provided to be openable and closable with respect to the body opening; a mounting stage provided in the cleaning space placing a shell of a wafer storage container; a first ejector that ejects a cleaning liquid into a storage space of the shell; a second ejector that ejects the cleaning liquid into an outer portion of the shell; a first discharge port that discharges the cleaning liquid ejected into the storage space of the shell; a second discharge port that discharges the cleaning liquid that has passed through the outer portion of the shell; and a particle counter that measures particles in the cleaning liquid discharged by the first discharge port.

### CROSS-REFERENCE TO RELATED APPLICATIONS

This application is based on and claims priority from Japanese Patent Application Nos. 2022-148809 and 2023-124167, filed on Sep. 20, 2022 and Jul. 31, 2023, respectively, with the Japan Patent Office, the disclosures of which are incorporated herein in their entireties by reference.

### TECHNICAL FIELD

The present disclosure relates to a cleaning apparatus for a wafer storage container.

### BACKGROUND

Cleaning apparatuses for wafer storage container, such as a front opening unified pod (FOUP) and a front opening shipping box (FOSB) that store (or contain) semiconductor wafers, have been used to clean and dry the wafer storage container (See, for example, Japanese Patent Laid-Open Publication No. 2005-109523).

### SUMMARY

In the wafer storage container, impurities (particles) may adhere to the inside of the storage space where semiconductor wafers are stored due to the opening and closing operation of the door (a lid unit) or the loading and unloading operation of semiconductor wafers. Therefore, at least the inside of the storage space is cleaned through the use of the wafer storage container cleaning apparatus. In this context, users of the storage container may want to ascertain the level of cleanliness within the storage space of the wafer storage container after the storage container is cleaned by the wafer storage container cleaning apparatus, based on the information on particles.

The present disclosure provides a wafer storage container cleaning apparatus capable of detecting information on particles, which indicates the level of cleanliness within the storage space of the wafer storage container after being cleaned.

According to an aspect of the present disclosure, a wafer storage container cleaning apparatus that cleans a wafer storage container including a shell and a door is provided. The shell has a shell opening and a storage space for storing a semiconductor wafer while communicating with the shell opening. The door is attached to be openable and closable with respect to the shell opening. The wafer storage container cleaning apparatus includes a cleaning tank body, a lid unit, a mounting unit, a first ejection unit, a second ejection unit, a first discharge unit, a second discharge unit, and a particle measurement unit. The cleaning tank body has a body opening and a cleaning space communicating with the body opening. The lid unit is provided to be openable and closable with respect to the body opening. The mounting unit is provided in the cleaning space, places the shell of the wafer storage container in a state where the shell opening of the shell faces the mounting stage, and is formed with a through hole at a portion that faces the shell opening of the shell to be communicated with the storage space. The first ejection unit ejects a cleaning liquid into the storage space of the shell. The second ejection unit ejects the cleaning liquid into an outer portion of the shell. The first discharge unit communicates with the through hole and discharges the cleaning liquid ejected into the storage space of the shell. The second discharge unit discharges the cleaning liquid that has passed through the outer portion of the shell. The particle measurement unit measures particles in the cleaning liquid discharged by the first discharge unit.

According to the embodiments of the present disclosure, it is possible to detect particle-related information that indicates the level of cleanliness in the storage space of the wafer storage container that has been cleaned.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an exemplary schematic configuration of a wafer storage container cleaning apparatus according to an embodiment.

FIG. 2 is a diagram schematically illustrating an exemplary configuration of a cleaning tank according to an embodiment.

FIG. 3 is a diagram schematically illustrating an exemplary configuration of the cleaning tank according to an embodiment.

FIG. 4 is a diagram illustrating an exemplary configuration of a control unit according to an embodiment.

FIG. 5 is a diagram illustrated to describe an exemplary configuration of each component provided in a flow channel through which cleaning liquid flows downstream of a first discharge unit according to an embodiment.

FIG. 6 is a flowchart illustrating an exemplary processing procedure executed by the wafer storage container cleaning apparatus according to an embodiment.

FIG. 7 is a diagram illustrating an exemplary configuration of a waste liquid measurement tank according to a fourth modified embodiment.

FIG. 8 is a diagram illustrating other modified embodiments.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Embodiments of a cleaning apparatus for wafer storage container (a wafer storage container cleaning apparatus) disclosed in the present disclosure are now described in detail with reference to the accompanying drawings. The wafer storage container cleaning apparatus disclosed in the present disclosure is not limited to the following embodiments. Furthermore, the respective embodiments and modified embodiments may be appropriately combined within a scope that avoids contradictions. In the following embodiments, descriptions will be made on a case where a wafer storage container to be cleaned is FOUP, but the wafer storage container to be cleaned is not limited to this type of container. For example, the wafer storage container to be cleaned may be FOSB.

### EMBODIMENTS

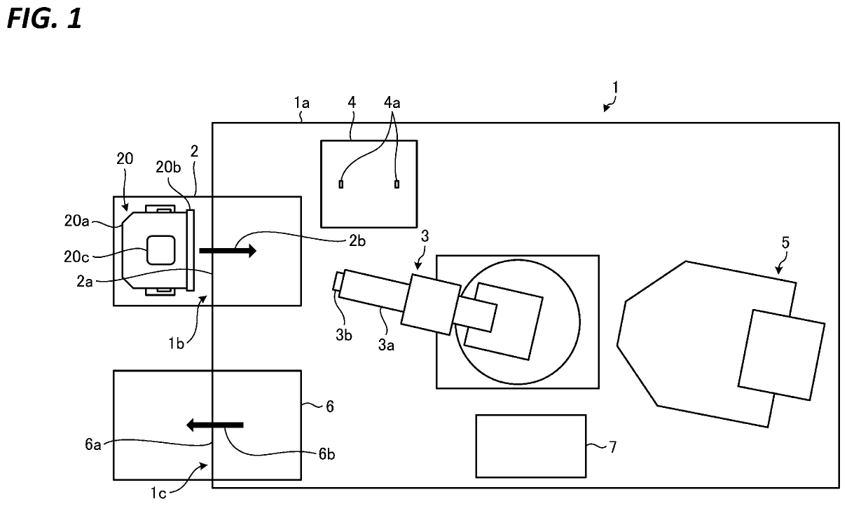

FIG. 1 is a plan view illustrating an exemplary schematic configuration of a wafer storage container cleaning apparatus 1 according to an embodiment. The wafer storage container cleaning apparatus 1 that cleans wafer storage container is provided, for example, in a factory that manufactures semiconductor wafers. As illustrated in FIG. 1, the wafer storage container cleaning apparatus 1 includes a loading port 2, a robot 3, a disassembly/connection stage 4, a cleaning tank 5, an unloading port 6, and a control unit 7.

The robot 3, the disassembly/connection stage 4, the cleaning tank 5, and the control unit 7 are provided inside a casing 1a of the wafer storage container cleaning apparatus 1. In the meantime, the loading port 2 and the unloading port 6 are provided across the inside and outside of the casing 1a of the wafer storage container cleaning apparatus 1.

The loading port 2 loads an FOUP 20, which is to be cleaned and is placed on the portion of the loading port 2 outside the casing 1a, into the inside of the casing 1a. The FOUP 20 includes a shell (FOUP body) 20a and a door (lid) 20b. The shell 20a has an opening (a shell opening) and a storage space for storing semiconductor wafers. The storage space exists farther inside than the shell opening and communicates with the shell opening. The door 20b is provided in an openable and closable state with respect to the shell opening. In addition, a flange 20c is provided on the upper portion of the shell 20a. The flange 20c is a portion that is gripped (held) when the FOUP 20 is transferred by overhead hoist transport (OHT), the robot 3, or the like. The OHT may hold not only the flange 20c but also the bottom surface of the FOUP 20.

For example, the FOUP 20, which is transferred with the flange 20c gripped by the OHT, is placed on the portion of the loading port 2 outside the casing 1a. As illustrated in, for example, FIG. 1, the FOUP 20 is placed in such a way that the door 20b of the FOUP 20 faces the casing 1a. When the FOUP 20 is placed on the loading port 2 in this manner, a shutter 2a provided at an opening 1b of the casing 1a is lifted. As a result, the FOUP 20 is capable of being loaded into the inside of the casing 1a through the opening 1b. That is, the FOUP 20 is capable of being loaded into the wafer storage container cleaning apparatus 1. Then, the FOUP 20 is slid in the direction as indicated by the arrow 2b, by a slide device of the loading port 2, so that the FOUP 20 is loaded into the casing 1a. The sliding by the slide device is now described. For example, the mounting surface of the FOUP 20 is fixed to the slide device by inserting a pin provided in the slide device into a hole provided in the bottom (a mounting surface) of the FOUP 20. In this state, the slide device is slid in the direction of the arrow 2b, and thus, the FOUP 20 is slid accordingly. As a result, the FOUP 20 is placed on a predetermined portion inside the casing 1a of the loading port 2. When the FOUP 20 is loaded into the casing 1a in this manner, the shutter 2a is lowered to close the opening 1b of the casing 1a. The slide device descends together with the pin to a position lower than the lower end of the shutter 2a (the mounting surface of the FOUP 20) which has been lowered, and returns to its original position outside the casing 1a.

The robot 3 transfers the FOUP 20 to each component in a state where the flange 20c of the FOUP 20 is gripped. The robot 3 has a robot arm 3a and a robot hand 3b. The robot 3 transfers the FOUP 20 to each component by expanding/contracting and rotational moving the robot arm 3a while the flange 20c is gripped by the robot hand 3b.

The disassembly/connection stage 4 disassembles the FOUP 20 into the shell 20a and the door 20b or connects (attaches) the shell 20a and the door 20b together. A latch key 4a is provided on the disassembly/connection stage 4. When the latch key 4a rotates while being inserted into a latch hole provided in the door 20b of the FOUP 20, the FOUP 20 is disassembled (separated) into the shell 20a and the door 20b, or the shell 20a and the door 20b are connected.

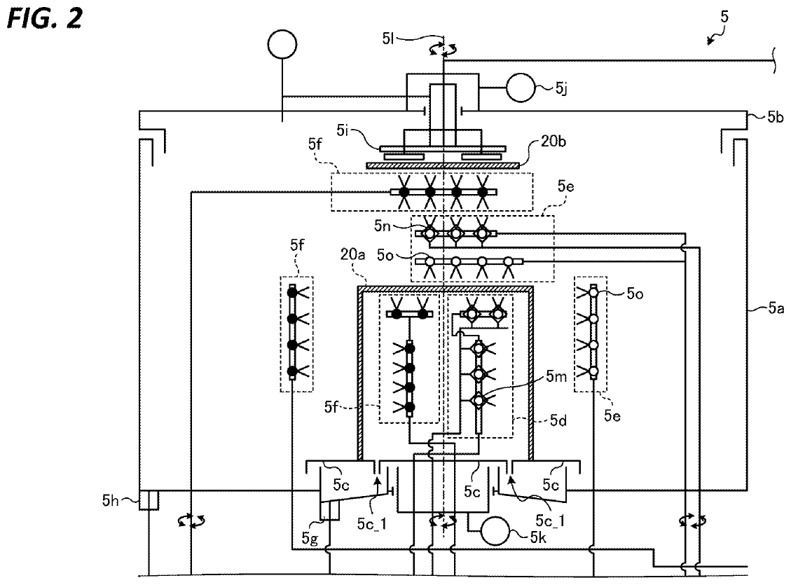

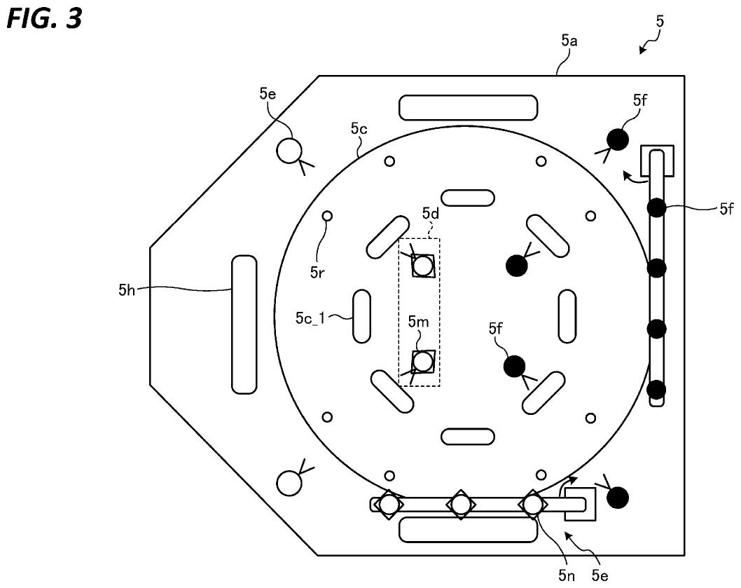

The cleaning tank 5 is a tank for cleaning the FOUP 20. The cleaning tank 5 is an example of a cleaning unit. FIGS. 2 and 3 are diagrams each schematically illustrating an exemplary configuration of the cleaning tank 5 according to an embodiment. FIG. 3 is a schematic plan view of the cleaning tank 5, and illustrates a state in which the FOUP 20 is not placed in the cleaning space. As illustrated in FIG. 2, the cleaning tank 5 includes, for example, a cleaning tank body 5a, a lid unit 5b, a mounting unit 5c, a first supply (a first ejection unit) 5d, a second supply (a second ejection unit) 5e, a drying unit 5f, a first discharge unit 5g, and a second discharge unit 5h.

The cleaning tank body 5a has an opening (a body opening) on its upper side and a cleaning space that communicates with the body opening. The cleaning space is a space that exists farther inside than the body opening. The robot 3 loads the shell 20a into the cleaning space through the body opening. In this manner, the shell 20a is loaded into the cleaning tank body 5a. Then, the loaded shell 20a is placed on the mounting unit 5c provided in the cleaning space of the cleaning tank body 5a. As illustrated in FIG. 2, the mounting unit 5c is a stage (a mounting stage) on which the shell 20a is mounted with the shell opening of the shell 20a directed downward. As illustrated in FIG. 3, the mounting unit 5c is provided with a positioning pin 5r. The position where the shell 20a is to be placed is determined by the positioning pin 5r. As illustrated in FIGS. 2 and 3, the mounting unit 5c is formed with a plurality of through holes 5c_1. The through hole 5c_1 communicates (connects) with the first discharge unit 5g.

The lid unit 5b is provided above the cleaning tank body 5a, and opens and closes with respect to the body opening of the cleaning tank body 5a by the operation of an air cylinder. A holding unit (a holding mechanism) 5i that is capable of holding the door 20b by suction is provided inside the lid unit 5b.

In the present embodiment, when the FOUP 20 is cleaned in the cleaning tank 5, the robot 3 separately transfers the shell 20a and the door 20b on the disassembly/connection stage 4 to the cleaning tank 5. For example, the robot 3 transfers the shell 20a from the opening of the cleaning tank body 5a into the inside of the cleaning tank body 5a with the opening of the shell 20a directed downward. Then, as illustrated in FIG. 2, the shell 20a is placed on the mounting unit 5c with the opening of the shell 20a directed downward. Furthermore, the robot 3 transfers the door 20b to the holding unit 5i so that the outer surface of the door 20b is held by the holding unit 5i of the lid unit 5b. As a result, when the lid unit 5b is closed as illustrated in FIG. 2, the inner surface (inner surface) of the door 20b is directed downward.

When the cleaning for the FOUP 20 is completed in the cleaning tank 5, the robot 3 separately transports the shell 20a and the door 20b in the cleaning tank 5 onto the disassembly/connection stage 4. Then, the disassembly/connection stage 4 connects the shell 20a and the door 20b.

Further, a first supply unit 5d and a second supply unit 5e are provided in the cleaning space of the cleaning tank body 5a. A cleaning liquid (e.g., pure water such as deionized water (DI water)) used for cleaning the shell 20a and the door 20b is supplied to the first supply unit 5d and the second supply unit 5e. Then, the first supply unit 5d supplies (ejects) the cleaning liquid to the storage space of the shell 20a, thereby cleaning the storage space. In addition, the second supply unit 5e supplies (ejects) the cleaning liquid to the outer portion of the shell 20a and the inner surface of the door 20b held by the holding unit 5i of the lid unit 5b, thereby cleaning the outer portion of the shell 20a and the inner surface of the door 20b.

The first supply unit 5d is provided at a position capable of supplying the cleaning liquid to the storage space of the shell 20a placed on the mounting unit 5c. For example, the first supply unit 5d includes at least one rod-shaped pipe extending upward from the surface of the mounting unit 5c on which the shell 20a is placed (in the present embodiment, two pipes are provided as illustrated in FIG. 3), at least one rod-shaped pipe extending in the horizontal direction (not illustrated in FIG. 3), and a plurality of nozzles 5m provided in each pipe. The nozzle 5m is, for example, a two-fluid nozzle. In the case where the nozzle 5m is the two-fluid nozzle, the nozzle 5m mixes the air (as an example of the gas) and the cleaning liquid, atomizes the cleaning liquid by the flow of air, and supplies the atomized cleaning liquid to the storage space of the shell 20a. The nozzle 5m is capable of supplying the cleaning liquid to the storage space without mixing the air and the cleaning liquid. That is, the nozzle 5m is capable of supplying non-atomized cleaning liquid to the storage space without atomizing the cleaning liquid.

The second supply unit 5e is provided at a position capable of supplying the cleaning liquid to the outer portion of the shell 20a and the inner surface of the door 20b. For example, the second supply unit 5e includes at least one rod-shaped pipe extending in the vertical direction (in the present embodiment, two pipes are provided as illustrated in FIG. 3), a plurality of rod-shaped pipes extending in the horizontal direction and capable of rotation, and a plurality of nozzles 5o or 5n provided in each pipe. The nozzle 5n is, for example, a two-fluid nozzle similar to the nozzle 5m, which is provided to eject toward the door 20b. In the case where the nozzle 5n is the two-fluid nozzle, the nozzle 5n supplies atomized cleaning liquid to the outer portion of the shell 20a and the inner surface of the door 20b. In addition, the nozzle 5o is, for example, a one-fluid nozzle. In the case where the nozzle 5o is the one-fluid nozzle, the nozzle 5o supplies the cleaning liquid to the outer portion of the shell 20a.

For example, in FIG. 2, the nozzle of the second supply unit 5e arranged between the shell 20a and the door 20b is retreated to a position that does not interfere with the shell 20a (i.e., a retreated position), as illustrated in FIG. 3, when the shell 20a is unloaded, loaded, and dried. After the shell 20a is loaded into the cleaning space and the lid unit 5b is closed with the door 20b held by the holding unit 5i, the nozzle of the second supply unit 5e rotates and moves to a position above the shell 20a placed on the mounting unit 5c and below the door 20b held by the holding unit 5i (i.e., a cleaning position). When the cleaning is completed, the nozzle rotationally moves to the retreated position.

The drying unit 5f is provided at a position capable of supplying the hot air (e.g., hot blow) to the storage space of the shell 20a, the outer portion of the shell 20a, and the inner surface of the door 20b. For example, the drying unit 5f includes at least one rod-shaped pipe extending vertically, at least one rod-shaped pipe extending horizontally, and a plurality of hot blow nozzles provided for each pipe. In the present embodiment, two vertically extending pipes and one horizontally extending pipe are provided for supplying the hot air to the storage space of the shell 20a when the shell 20a is placed. In addition, two vertically extending pipes and one horizontally extending rotatable pipe are provided for supplying the hot air to the outer portion of the shell 20a. The hot blow nozzles provided on these pipes supply the hot air to the storage space of the shell 20a, the outer portion of the shell 20a, and the inner surface of the door 20b.

For example, in FIG. 2, the drying unit 5f arranged between the shell 20a and the door 20b is retreated to a position that does not interfere with the shell 20a (i.e., a retreated position), as illustrated in FIG. 3, when the shell 20a is unloaded, loaded, and cleaned. Then, when the cleaning is completed, the drying unit 5f rotationally moves to a position above the shell 20a placed on the mounting unit 5c and below the door 20b held by the holding unit 5i (i.e., a drying position). When the drying is completed, it rotationally moves to the retreated position.

Further, the cleaning tank body 5a is equipped with a first rotation unit including a motor 5k. The first rotation unit rotates the mounting unit 5c about a shaft 5l extending in the vertical direction as a rotation axis during the cleaning of the shell 20a and hot blowing. As the mounting unit 5c rotates, the shell 20a mounted on the mounting unit 5c rotates accordingly. In addition, the lid unit 5b is equipped with a second rotation unit including a motor 5j. The second rotation unit rotates the holding unit 5i about the shaft 5l as a rotation axis during the cleaning and drying for the door 20b. As the holding unit 5i rotates, the door 20b held by the holding unit 5i rotates accordingly. Therefore, the cleaning liquid is evenly supplied to the FOUP 20 during cleaning for the FOUP 20. In addition, the hot blow is supplied to the FOUP 20 seamlessly during the drying for the FOUP 20. Alternatively, the liquid adhering to the shell 20a and the door 20b may be dried through the rotation by the first rotation unit and the second rotation unit, respectively, without supplying the hot blow from the hot blow nozzle.

The first discharge unit 5g discharges the cleaning liquid supplied (ejected) to the storage space of the shell 20a. As described above, the first discharge unit 5g communicates (connects) with the through hole 5c_1. Therefore, the cleaning liquid supplied to the storage space of the shell 20a flows into the first discharge unit 5g via the through hole 5c_1. A particle counter 38, which will be described later, is provided in a flow channel through which the cleaning liquid flows downstream of the first discharge unit 5g.

The second discharge unit 5h discharges the cleaning liquid that has passed through the outside of the shell 20a. The cleaning liquid that has passed through the outside of the shell 20a is a cleaning liquid that is supplied (ejected) to the outer portion of the shell 20a and the inner surface of the door 20b. For example, the second discharge unit 5h is a discharge port provided at the bottom of the cleaning tank body 5a.

Referring back to the description of FIG. 1, the unloading port 6 unloads the FOUP 20 completed with cleaning and placed by the robot 3 on the inside of the casing 1a of the unloading port 6 into the outside of the casing 1a.

For example, the FOUP 20 connected with the shell 20a and the door 20b in the disassembly/connection stage 4 after cleaning is transferred by the robot 3 and is placed inside the casing 1a of the unloading port 6. When the FOUP 20 is placed on the unloading port 6 in this way, a shutter 6a provided at an opening 1c of the casing 1a is lifted. As a result, the FOUP 20 is capable of being unloaded out to the outside of the casing 1a through the opening 1c. That is, the FOUP 20 is capable of being unloaded out to the outside of the wafer storage container cleaning apparatus 1. Then, the FOUP 20 is slid in the direction indicated with the arrow 6b by a slide device of the unloading port 6 (having a similar mechanism to the slide device of the loading port 2), so that the FOUP 20 is unloaded out to the outside of the casing 1a. When the FOUP 20 is unloaded out to the outside of the casing 1a in this manner, the shutter 6a is lowered, and the opening 1c of the casing 1a is closed.

The control unit 7 controls the overall operation of the wafer storage container cleaning apparatus 1. For example, the control unit 7 controls the loading port 2, the robot 3, the disassembly/connection stage 4, the cleaning tank 5, and the unloading port 6, so that the loading port 2, the robot 3, the disassembly/connection stage 4, the cleaning tank 5, and the unloading port 6 operate, as described above.

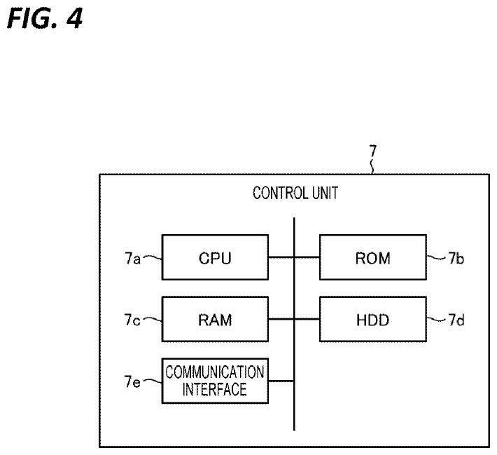

FIG. 4 is a diagram illustrating an exemplary configuration of the control unit 7 according to an embodiment. As illustrated in FIG. 4, the control unit 7 includes a central processing unit (CPU) 7a, a read-only memory (ROM) 7b, a random-access memory (RAM) 7c, a hard disk drive (HDD) 7d, and a communication interface 7e. These components are interconnected via an internal bus.

The CPU 7a executes various processes while using the memory area of the RAM 7c as a temporary working area for data used in various processes. The processing executed by the CPU 7a will be described later. The ROM 7b and the HDD 7d store programs for executing various processes, various databases, various tables, and the like used when executing various processes.

The communication interface 7e is an interface for communicating with the above-described components of the wafer storage container cleaning apparatus 1 and communicating with an external device connected to the wafer storage container cleaning apparatus 1 via a network. For example, the communication interface 7e is a network interface card.

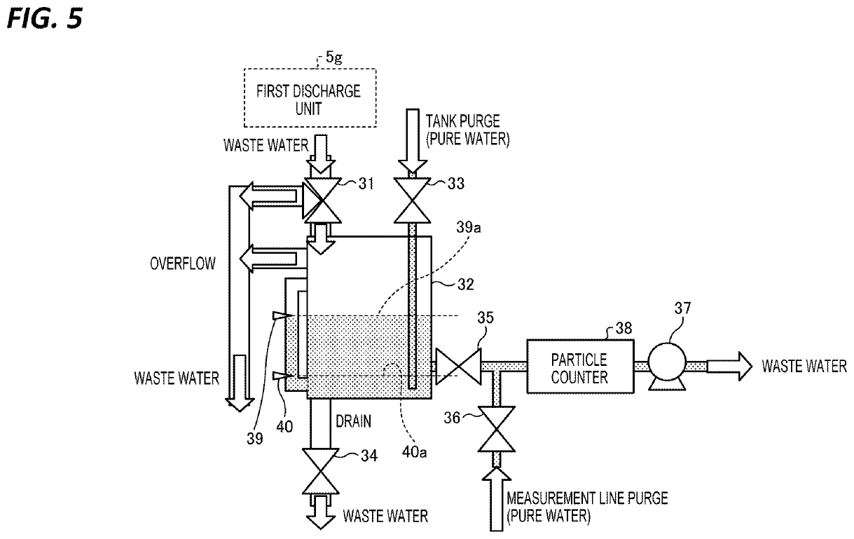

Then, an exemplary configuration of each component provided in the flow channel through which the cleaning liquid flows downstream of the first discharge unit 5g of the wafer storage container cleaning apparatus 1 is described. FIG. 5 is a diagram illustrating an exemplary configuration of each component provided in the flow channel through which the cleaning liquid flows downstream of the first discharge unit 5g according to an embodiment.

As illustrated in FIG. 5, the flow channel through which the cleaning liquid flows downstream of the first discharge unit 5g is provided with a three-way valve 31, a waste liquid measurement tank 32, air-operated (AO) valves 33 to 36, a pump 37, the particle counter 38, and liquid level sensors 39 and 40. In the following description, the AO valve 33 may be referred to as a first AO valve 33, the AO valve 34 as a second AO valve 34, the AO valve 35 as a third AO valve 35, and the AO valve 36 as a fourth AO valve 36.

The three connection ports of the three-way valve 31 are connected to the first discharge unit 5g, the waste liquid side (left side in FIG. 5), and the waste liquid measurement tank 32, respectively. For example, the cleaning liquid discharged by the first discharge unit 5g flows into the three-way valve 31 as waste liquid. Then, the waste liquid flowing into the three-way valve 31 flows out to either the waste liquid side or the waste liquid measurement tank 32 under the control of the control unit 7.

The waste liquid that contains particles measured by the particle counter 38 is reserved in the waste liquid measurement tank 32.

The first AO valve 33 is provided in a flow channel through which the pure water flows toward the waste liquid measurement tank 32. By opening the first AO valve 33, the pure water is supplied to the waste liquid measurement tank 32. By closing the first AO valve 33, the supply of pure water to the waste liquid measurement tank 32 is stopped.

The second AO valve 34 is provided in a flow channel through which the waste liquid flows out from the waste liquid measurement tank 32. By opening the second AO valve 34, the waste liquid flows out from the waste liquid measurement tank 32. By closing the second AO valve 34, the outflow of the waste liquid from the waste liquid measurement tank 32 is stopped.

The third AO valve 35 is provided in a flow channel through which the waste liquid flows from the waste liquid measurement tank 32 toward the particle counter 38. By opening the third AO valve 35, the waste liquid from the waste liquid measurement tank 32 is supplied to the particle counter 38. By closing the third AO valve 35, the supply of the waste liquid to the particle counter 38 is stopped.

The fourth AO valve 36 is provided in a flow channel through which the pure water flows toward the particle counter 38. By opening the fourth AO valve 36, the pure water is supplied to the particle counter 38 and its flow channel (or a measurement line). By closing the fourth AO valve 36, the supply of pure water to the particle counter 38 and its flow channel (the measurement line) is stopped.

The pump 37 operates to draw in the waste liquid or pure water.

The particle counter 38 measures particles contained in the supplied waste liquid and outputs information on particles. For example, the particle counter 38 measures the number of particles contained in a predetermined unit volume of waste liquid (e.g., 10 ml). Then, the particle counter 38 outputs the number of particles contained in the predetermined unit volume of waste liquid to the control unit 7 as information on particles. The particle counter 38 is an example of a particle measurement unit.

The liquid level sensor 39 is provided at a position higher in height than the liquid level sensor 40 and detects whether or not the liquid level of the waste liquid reserved in the waste liquid measurement tank 32 reaches a height 39a that is identical to the height of the liquid level sensor 39. The liquid level sensor 39 performs such detection at predetermined time intervals. Then, the liquid level sensor 39 outputs the result obtained by the detection to the control unit 7 at predetermined time intervals.

The liquid level sensor 40 detects whether or not the liquid level of the waste liquid reserved in the waste liquid measurement tank 32 reaches a height 40a that is identical to the height of the liquid level sensor 40. The liquid level sensor 40 performs such detection at predetermined time intervals. Then, the liquid level sensor 40 outputs the result obtained by the detection to the control unit 7 at predetermined time intervals.

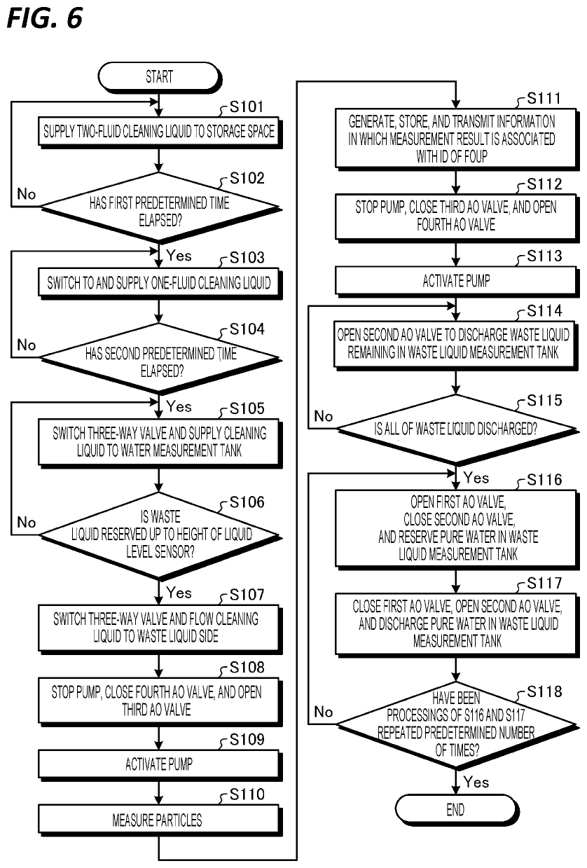

Subsequently, an example of processing executed by the wafer storage container cleaning apparatus 1 is described. FIG. 6 is a flowchart illustrating an exemplary procedure of the processing executed by the wafer storage container cleaning apparatus 1 (operation of the wafer storage container cleaning apparatus 1) according to an embodiment. The processing illustrated in FIG. 6 is performed in the case where the FOUP 20 is cleaned in the cleaning tank 5. The processing illustrated in FIG. 6 is, for example, a processing executed by each component other than the control unit 7 under the control of the control unit 7.

The cleaning tank 5 begins cleaning the FOUP 20. In this event, the nozzle 5m of the first supply unit 5d supplies, for example, an atomized cleaning liquid (two-fluid) to the storage space of the shell 20a (step S101). In addition, in this event, the three-way valve 31 flows out the waste liquid discharged from the first discharge unit 5g to the waste liquid side.

Subsequently, the CPU 7a of the control unit 7 determines whether or not a first predetermined time has elapsed after beginning the cleaning of the FOUP 20 (beginning the supply of cleaning liquid of two-fluid cleaning liquid (two-fluid cleaning liquid)) (step S102). This first predetermined time is, for example, the time required for one cleaning cycle of the FOUP 20 by the cleaning tank 5 (e.g., cleaning time).

When the first predetermined time has not elapsed since the beginning of the cleaning of the FOUP 20 (step S102: No), the supply of the cleaning liquid continues, and the CPU 7a performs the determination of step S102 again. In the meantime, when the first predetermined time has elapsed since the beginning of the cleaning of the FOUP 20 (step S102: Yes), the nozzle 5m of the first supply unit 5d begins supplying non-atomized cleaning liquid (or pure water) to the storage space without mixing air and the cleaning liquid (step S103). That is, in step S103, the nozzle 5m switches the fluid ejected from the nozzle 5m from a two-fluid mixture of air and cleaning liquid to pure water (one-fluid).

Subsequently, the CPU 7a determines whether or not a second predetermined time has elapsed after switching to pure water in step S103 (step S104). This second predetermined time is, for example, a time duration during which all of the two-fluid liquid is discharged from the storage space.

When the second predetermined time has not elapsed after switching to pure water (step S104: No), the supply of cleaning liquid of one-fluid (one-fluid cleaning liquid) continues, and the CPU 7a performs the determination of step S104 again. In the meantime, when the second predetermined time has elapsed after switching to pure water (step S104: Yes), the CPU 7a switches the three-way valve 31 to allow the waste liquid flowing into the three-way valve 31 (pure water, which is the one-fluid cleaning liquid) to flow out into the waste liquid measurement tank 32 (step S105). That is, the CPU 7a controls the three-way valve 31 so that the waste liquid flows out into the waste liquid measurement tank 32. In this event, the first AO valve 33, the second AO valve 34, and the third AO valve 35 are closed, while the fourth AO valve 36 is opened. In addition, the pump 37 starts its operation at the timing when the two-fluid cleaning liquid is supplied to the storage space in step S101, and the pure water is supplied to the particle counter 38. This is a process to ensure that the particle measurement region is clean before the measurement begins by the particle counter 38.

Then, the CPU 7a determines whether or not the waste liquid is reserved in the waste liquid measurement tank 32 up to the same height 39a as the height of the liquid level sensor 39, based on the detection results output from the liquid level sensor 39 at predetermined time intervals (step S106).

When the waste liquid is not reserved up to the same height 39a as the height of the liquid level sensor 39 (step S106: No), the waste liquid continues to be discharged to the waste liquid measurement tank 32, and the CPU 7a performs the determination of step S106 again. In the meantime, when the waste liquid is reserved up to the same height 39a as the height of the liquid level sensor 39 (step S106: Yes), the CPU 7a switches the three-way valve 31 so that the waste liquid flowing into the three-way valve 31 flows out to the waste liquid side (step S107). That is, the CPU 7a controls the three-way valve 31 so that the waste liquid flows out to the waste liquid side.

Subsequently, the CPU 7a stops the pump 37, closes the fourth AO valve 36, and opens the third AO valve 35 (step S108).

Subsequently, the CPU 7a activates the pump 37 to feed the waste liquid in the waste liquid measurement tank 32 to the particle counter 38 (step S109).

Subsequently, the particle counter 38 measures the number of particles contained in the predetermined unit volume of waste liquid and outputs the number of particles contained in the predetermined unit volume of waste liquid to the control unit 7 as information on particles (step S110). The particle counter 38 may perform such measurements multiple times and output an average value of results obtained by the measurement multiple times (the number of particles contained in the predetermined unit volume of waste liquid) to the control unit 7 as the final measurement result. For example, the particle counter 38 may measure the fed waste liquid multiple times at predetermined time intervals and output the average value of the measurement results to the control unit 7. Alternatively, the storage in the waste liquid measurement tank 32 and the measurement by the particle counter 38 may be repeated multiple times, and the average value of the results obtained by the multiple measurements in the particle counter 38 may be output to the control unit 7. In this case, it is possible to achieve accurate measurement by interposing a process of discharging the waste liquid in the waste liquid measurement tank 32 in step S115, and a process of reserving pure water in the waste liquid measurement tank in step S116 and discharging the pure water in the waste liquid measurement tank in step S117, which will be described later.

Subsequently, the CPU 7a generates information where the measurement result is associated with an individual identification number (ID) of the FOUP 20, stores the generated information in the HDD 7d, and controls the communication interface 7e so that the information is output to an external device that centrally manages all the FOUPs in the factory (step S111). For example, the control unit 7 includes an ID reading unit, and the ID reading unit reads an identification (ID) that is identification information of the FOUP 20, provided in the FOUP 20. The ID reading unit is an example of the reading unit. For example, the ID of the FOUP 20 may be obtained by a barcode scanner (or a barcode reader) that is the ID reading unit. For example, the barcode scanner reads a barcode indicating an individual identification number of the FOUP 20 as the ID of the FOUP 20 and transmits the individual identification number indicated by the read barcode to the CPU 7a. Further, for example, the ID reading unit may be a reader capable of reading the individual identification number of the FOUP 20, which is output as the ID of the FOUP 20 from an RF tag provided in the FOUP 20. In this case, the reader transmits the read individual identification number to the CPU 7a. Further, instead of outputting the particle measurement results to an external device that centrally manages all the FOUPs in the factory, information on the measurement result may be recorded in the RF tag provided in the FOUP 20.

By the processing in step S111, the communication interface 7e outputs information regarding particles measured by the particle counter 38. The communication interface 7e is an example of an output unit. Further, by the processing in step S111, the HDD 7d stores the history of information on particles, which is associated with the FOUP 20 (e.g., the ID of the FOUP 20).

Subsequently, the CPU 7a stops the pump 37, closes the third AO valve 35, and opens the fourth AO valve 36 (step S112).

The CPU 7a then activates the pump 37 to feed pure water to the particle counter 38 and its flow channel, thereby performing a purging operation of the flow channel (step S113).

Subsequently, the CPU 7a opens the second AO valve 34 to discharge the waste liquid remaining in the waste liquid measurement tank 32 (step S114).

The CPU 7a then determines whether or not all of the waste liquid remaining in the waste liquid measurement tank 32 is discharged from the waste liquid measurement tank 32 (step S115). For example, when a predetermined time has elapsed after the liquid level of the waste liquid reaches the same height 40a as the height of the liquid level sensor 40, the CPU 7a determines that all of the waste liquid remaining in the waste liquid measuring tank 32 is discharged from the waste liquid measuring tank 32, based on the detection result output from the liquid level sensor 40 at predetermined time intervals. In the meantime, when a predetermined time has not elapsed after the liquid level of the waste liquid reaches the same height 40a as the height of the liquid level sensor 40, the CPU 7a determines that not all of the waste liquid remaining in the waste liquid measurement tank 32 is discharged from the waste liquid measurement tank 32.

When the waste liquid remaining in the waste liquid measurement tank 32 is not entirely discharged from the waste liquid measurement tank 32 (step S115: No), the discharge of the waste liquid continues, and the CPU 7a performs the determination of step S115 again. In the meantime, when the waste liquid remaining in the waste liquid measurement tank 32 is entirely discharged from the waste liquid measurement tank 32 (step S115: Yes), the CPU 7a opens the first AO valve 33 and closes the second AO valve 34 (step S116). As a result, pure water is supplied to the waste liquid measurement tank 32, and the pure water is reserved in the waste liquid measurement tank 32. In step S116, the waste liquid measurement tank 32 collects the pure water until the pure water overflows. The time required for the overflow to occur may be obtained in advance, and the pure water may be supplied continuously to the waste liquid measurement tank 32 for the obtained time duration.

Subsequently, the CPU 7a closes the first AO valve 33 and opens the second AO valve 34 (step S117). As a result, the pure water in the waste liquid measurement tank 32 is discharged from the waste liquid measurement tank 32.

The CPU 7a then determines whether or not the processing in steps S116 and S117 has been repeated a predetermined number of times (step S118). The inside of the waste liquid measurement tank 32 is purged by repeating the processing in steps S116 and S117 a predetermined number of times.

When the processing in steps S116 and S117 has not been repeated a predetermined number of times (step S118: No), the CPU 7a returns to step S116 and performs the processing after step S116 again. In the meantime, when the processing in steps S116 and S117 is repeated a predetermined number of times (step S118: Yes), the CPU 7a ends the processing illustrated in FIG. 6.

In the above, descriptions have been made on the wafer storage container cleaning apparatus 1 according to the embodiment. As described above, the wafer storage container cleaning apparatus 1 cleans the FOUP 20 that includes the shell 20a and the door 20b. The shell 20a has a shell opening and a storage space communicating with the shell opening serving as a storage space for storing semiconductor wafers. The door 20b is mounted to be openable and closable with respect to the shell opening. The wafer storage container cleaning apparatus 1 includes the cleaning tank body 5a, the lid unit 5b, the mounting unit 5c, the first supply unit 5d, the second supply unit 5e, the first discharge unit 5g, the second discharge unit 5h, and the particle measurement unit 38. The cleaning tank body 5a has the body opening and the cleaning space communicating with the body opening. The lid unit 5b is provided to be openable and closable with respect to the body opening. The mounting unit 5c is provided in the cleaning space, places the shell 20a with the shell opening of the shell faces the mounting unit, and is formed with the through hole 5c_1 in a portion that faces the shell opening to be communicated with the storage space. The first supply unit 5d supplies the cleaning liquid into the storage space of the shell 20a. The second supply unit 5e supplies the cleaning liquid to the outer portion of the shell 20a. The first discharge unit 5g communicates with the through hole 5c_1 and discharges the cleaning liquid supplied to the storage space of the shell 20a. The second discharge unit 5h discharges the cleaning liquid that passes through the outer portion of the shell 20a. The particle measurement unit 38 measures particles in the cleaning liquid discharged by the first discharge unit 5g.

In this way, the cleaning liquid supplied to the storage space of the shell 20a and the cleaning liquid that has passed through the outer portion of the shell 20a are separated and discharged as waste liquid. Thus, it is possible to supply only the cleaning liquid supplied to the storage space of the shell 20a to the particle counter 38. Therefore, the wafer storage container cleaning apparatus 1 according to the embodiment is capable of detecting particle-related information indicating the level of cleanliness in the storage space of the FOUP 20 completed with cleaning.

### First Modified Embodiment

Subsequently, a wafer storage container cleaning apparatus 1 according to a first modified embodiment is described. The wafer storage container cleaning apparatus 1 according to the first modified embodiment differs from the wafer storage container cleaning apparatus 1 according to the embodiment described above in that the FOUP 20 is additionally cleaned in the case where the number of particles contained in a predetermined unit volume of waste liquid measured by the particle counter 38 is equal to or greater than a predetermined value.

In the first modified embodiment, at the time when the first predetermined time as described above has elapsed after the cleaning of the FOUP 20 is started, the CPU 7a of the control unit 7 determines whether or not the number of particles contained in the predetermined unit volume of waste liquid is equal to or greater than the predetermined value. The first predetermined time is, for example, the cleaning time required for one cleaning cycle of the FOUP 20 by the cleaning tank 5, as described above.

When the number of particles contained in the predetermined unit volume of waste liquid is less than a predetermined value, the CPU 7a controls the cleaning tank 5 so that the cleaning is completed. In the meantime, when the number of particles contained in the predetermined unit volume of waste liquid is equal to or greater than the predetermined value, the CPU 7a controls the cleaning tank 5 so that the FOUP 20 is additionally cleaned for an additional cleaning time. Then, at the time when the additional cleaning time has elapsed after the additional cleaning of the FOUP 20 is started, the particle counter 38 measures the number of particles contained in the predetermined unit volume of waste liquid again. Then, the CPU 7a determines whether or not the number of particles contained in the predetermined unit volume of waste liquid is equal to or greater than the predetermined value again. Then, the CPU 7a repeats the processing that is similar to the processing described above until the number of particles contained in the predetermined unit volume of waste liquid becomes less than the predetermined value. When the number of times that it is determined that the number of particles contained in the predetermined unit volume of waste liquid is equal to or greater than the predetermined value reaches a predetermined number of times, the CPU 7a may end the cleaning and control the unloading port 6 so that it discharges the relevant FOUP 20 as a disqualified product. Additionally, when the ratio of the number of the FOUPs 20 that need to be cleaned during the additional cleaning time to the number of the FOUPs 20 processed per unit time exceeds a predetermined ratio (e.g., 10%), the CPU 7a may change the time obtained by adding the additional cleaning time to the first predetermined time as a new first predetermined time. Further, the additional cleaning time may be constant, but the CPU 7a may change the additional cleaning time according to the ratio. For example, the CPU 7a may set the additional cleaning time to be longer as the rate of excess increases.

In the first modified embodiment, the CPU 7a may determine the additional cleaning time based on the number of particles contained in the predetermined unit volume of the waste liquid. For example, the CPU 7a may determine the additional cleaning time to be longer as the number of particles contained in the predetermined unit volume of the waste liquid increases.

In the above, descriptions have been made on the wafer storage container cleaning apparatus 1 according to the first modified embodiment. In the first modified embodiment, when the number of particles measured by the particle counter 38 after the FOUP 20 is cleaned for the first predetermined time (the predetermined cleaning time) is equal to or greater than the predetermined value, the control unit 7 controls so that the FOUP 20 is cleaned additionally.

According to the wafer storage container cleaning apparatus 1 according to the first modified embodiment, additional cleaning is performed when the cleaning of the FOUP 20 is insufficient, and thus, it is possible to provide the FOUP 20 that meets the criteria for the level of cleanliness.

### Second Modified Embodiment

Subsequently, a wafer storage container cleaning apparatus 1 according to a second modified embodiment is described. The wafer storage container cleaning apparatus 1 according to the second modified embodiment feeds the waste liquid discharged from the first discharge unit 5g into the particle counter 38 without reserving the waste liquid in the waste liquid measurement tank 32, and measures the number of particles contained in the predetermined unit volume of the waste liquid. Then, the wafer storage container cleaning apparatus 1 continues cleaning the FOUP 20 until the number of particles contained in the predetermined unit volume of waste liquid becomes less than a predetermined value. The wafer storage container cleaning apparatus 1 ends the cleaning when the number of particles becomes less than the predetermined value. Therefore, according to the wafer storage container cleaning apparatus 1 according to the second modified embodiment, similar to the first modified embodiment, it is possible to provide the FOUP 20 that meets the criteria for the level of cleanliness. In the second modified embodiment, the two-fluid cleaning liquid used for the cleaning may be fed to the particle counter 38 as it is, or the cleaning liquid may be switched from two-fluid to one-fluid at a predetermined timing to perform measurements by the particle counter 38 at the time when a predetermined time has elapsed after the switching to one-fluid.

Further, there are cases where the cleaning is sufficient even when the cleaning time is shorter than the first predetermined time described above, depending on the level of cleanliness (e.g., a contamination level) of the FOUP 20. In the second modified embodiment, the waste liquid is fed to the particle counter 38 without being reserved in the waste liquid measurement tank 32, and the control unit 7 controls so that the cleaning of the FOUP 20 is completed according to the information on particles measured by the particle counter 38. Therefore, it is possible to efficiently clean the FOUP 20.

In the second modified embodiment, the waste liquid discharged from the first discharge unit 5g may be fed to the particle counter 38 while being reserved in the waste liquid measurement tank 32.

Further, in the case where the upper limit of the cleaning time is set in advance, when the cleaning time reaches the upper limit while the number of particles contained in the predetermined unit volume of waste liquid, when measured, is equal to or greater than the predetermined value, the cleaning of the FOUP 20 may end, and the relevant FOUP 20 may be discharged as a disqualified product.

### Third Modified Embodiment

Subsequently, a wafer storage container cleaning apparatus 1 according to a third modified embodiment is described. The wafer storage container cleaning apparatus 1 according to the third modified embodiment determines the above-described first predetermined time based on information on the wafer stored in the FOUP 20. The ID reading unit acquires, from the RF tag provided on the FOUP 20, information on the process in which the FOUP 20 loaded into the wafer storage container cleaning apparatus 1 was being used before being loaded into the wafer storage container cleaning apparatus 1. As a result, it is possible to specify the types of wafers stored in the FOUP 20 (e.g., including types of films formed on the wafer). The time required to clean the FOUP 20 (e.g., the first predetermined time) is determined according to the specified wafer type. Therefore, it is possible to efficiently clean the FOUP 20.

### Fourth Modified Embodiment

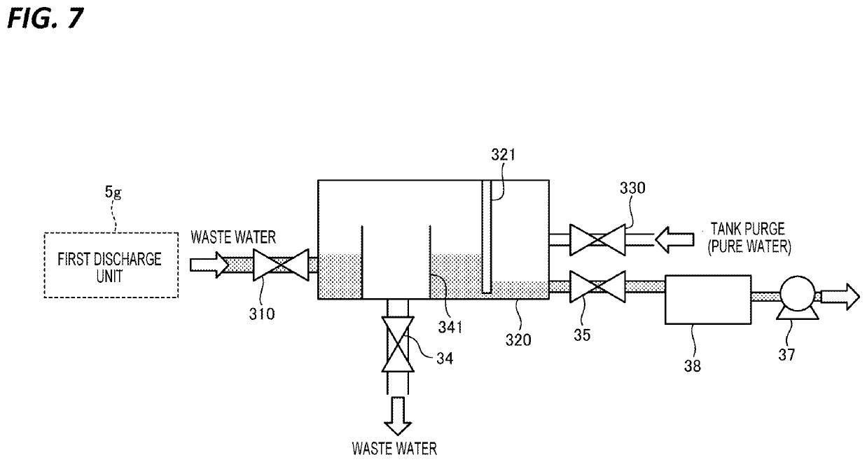

Subsequently, a wafer storage container cleaning apparatus 1 according to a fourth modified embodiment is described. The wafer storage container cleaning apparatus 1 according to the fourth modified embodiment includes a waste liquid measurement tank 320 instead of the waste liquid measurement tank 32. The waste liquid measurement tank 320 is described with reference to FIG. 7.

FIG. 7 is a diagram illustrating an exemplary configuration of the waste liquid measurement tank 320 according to the fourth modified embodiment. As illustrated in FIG. 7, the waste liquid measurement tank 320 is provided with an AO valve 310 and an AO valve 330 instead of the three-way valve 31 and the first AO valve 33, respectively. An overflow wall 341 and a barrier 321 are provided inside the waste liquid measurement tank 320. The overflow wall 341 is a cylindrical tube, and its upper end is opened toward the inside of the waste liquid measurement tank 320. A bottom end of the overflow wall 341 is connected to a bottom surface of the waste liquid measurement tank 320, the bottom surface of the waste liquid measurement tank 320, to which the bottom end of the overflow wall 341 is connected, is connected to a pipe in which the second AO valve 34 is provided, and a lower end of the overflow wall 341 communicates with the pipe in which the second AO valve 34 is provided. The barrier 321 is a plate-shaped member provided to divide the space inside the waste liquid measurement tank 320 into two sides: one where the overflow wall 341 is provided, and the other where a pipe leading to the particle counter 38 and a pipe for purging the waste liquid measurement tank 320 with pure water are provided. The barrier 321 has an upper end provided on the ceiling of the waste liquid measurement tank 320 and a lower end provided at a position forming a slight gap from the bottom surface of the waste liquid measurement tank 320.

The height position at which the pipe supplied with the waste liquid from the first discharge unit 5g is connected to the waste liquid measurement tank 320 is provided at a position lower than the upper end of the overflow wall 341. When the pipe is provided at a height position far away from the bottom surface of the waste liquid measurement tank 320, the waste liquid to be newly supplied may fall on the liquid surface of the waste liquid reserved in the waste liquid measurement tank 320, generating many air bubbles in the waste liquid. When the waste liquid containing air bubbles is fed to the particle counter 38, the air bubbles will be erroneously detected as particles, failing to perform an accurate measurement. Therefore, the height position at which the pipe supplied with the waste liquid from the first discharge unit 5g is connected to the waste liquid measurement tank 320 may be provided at a height position close to the bottom surface of the waste liquid measurement tank 320.

Further, the position at which the pipe for supplying pure water provided with the AO valve 330 is connected to the waste liquid measurement tank 320 is provided on the side of the third AO valve 35 of the waste liquid measurement tank 320 partitioned by the barrier 321 as described above. As a result, it is possible to sufficiently purge the vicinity of the pipe that is fed to the particle counter 38. Other configurations or structures are similar to the above-described embodiments.

In step S101 in the above-described embodiment, when the two-fluid cleaning liquid is supplied to the storage space, the waste liquid discharged from the first discharge unit 5g is supplied to the waste liquid measurement tank 320 through the AO valve 310 being open. That is, the above-described embodiment exemplifies the supply of waste liquid to the waste liquid measurement tank 32 after the first predetermined time has elapsed and the second predetermined time has elapsed, but in the present modified embodiment, all of the supplied cleaning liquid is supplied to the waste liquid measuring tank 320 without waiting for the passage of the first predetermined time and the second predetermined time. The waste liquid supplied to the inside of the waste liquid measurement tank 320 continues to be reserved in the waste liquid measurement tank 320, and when it overflows beyond the overflow wall 341, the overflowing waste liquid is discharged from the side of the AO valve 34. A portion of the waste liquid reserved in the waste liquid measurement tank 320 is reserved from below the barrier 321 toward the side of the third AO valve 35. When the first predetermined time has elapsed (S102: Yes), the cleaning liquid is switched to the one-fluid. When the second predetermined time has elapsed (step S104: Yes), the third AO valve 35 is opened, and the pump 37 is activated to perform the measurement by the particle counter 38. The second predetermined time herein may be set to the extent of time during which the one-fluid cleaning liquid starting the supply after the lapse of the first predetermined time is replaced by the two-fluid cleaning liquid that was being supplied before the lapse of the first predetermined time in the waste liquid measuring tank 320. According to the waste liquid measurement tank 320, the waste liquid, which contains many air bubbles and is reserved above the waste liquid measurement tank 320, is discharged beyond the overflow wall 341. In addition, the waste liquid reserved below the waste liquid measurement tank 320, which is difficult to contain air bubbles, passes through the gap below the barrier 321 and is fed to the particle counter 38. Therefore, it is possible to prevent the particle counter 38 from measuring waste liquid containing air bubbles and erroneously detecting air bubbles as particles. In addition, by providing the overflow wall 341 in the waste liquid measurement tank 320 so that all of the waste liquid from the first discharge unit 5g is supplied to the waste liquid measurement tank 320, the waste liquid is constantly reserved in the waste liquid measurement tank 320, and thus it is not necessary to provide liquid level sensors 39 and 40 to measure the amount of waste liquid reserved.

The waste liquid discharged from the first discharge unit 5g may be the two-fluid used for the cleaning without switching to the one-fluid. Since the waste liquid from which air bubbles are removed in the process of passing through the overflow wall 341 and the barrier 321 is easily supplied to the particle counter 38, it is possible to prevent an erroneous detection by the particle counter 38 even with the use of two-fluid cleaning liquid. In this case, it is possible to always perform the measurement by the particle counter 38 without waiting for the first predetermined time and the second predetermined time to elapse.

### Other Modified Embodiments

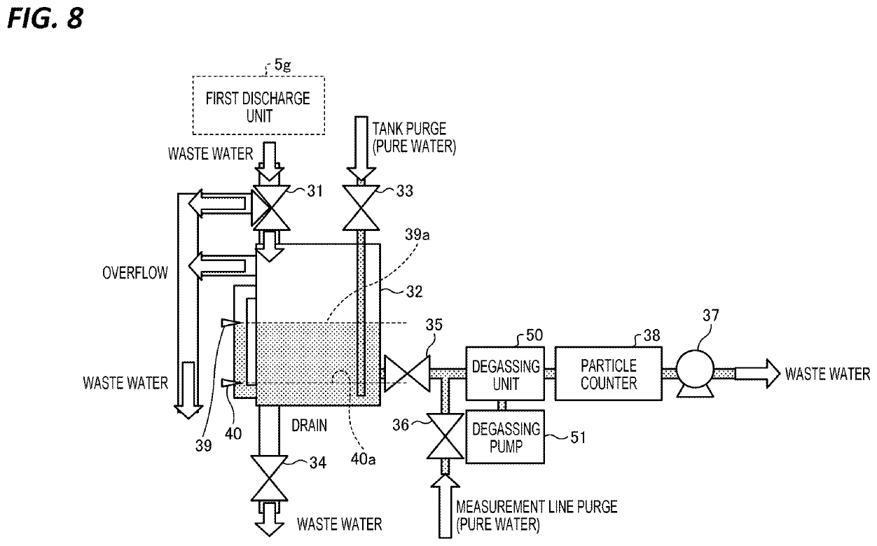

Subsequently, other modifications are described. FIG. 8 is a diagram illustrates other modified embodiments. For example, air bubbles contained in the waste liquid may affect the measurement by the particle counter 38. For this reason, as illustrated in FIG. 8, a degassing unit 50 and a degassing pump 51 may be provided upstream of the particle counter 38 to enable the degassing unit 50 and the degassing pump 51 to degas the waste liquid supplied to the particle counter 38. In this case, there is no need to control so that the fluid discharged from the nozzle 5m is switched from two-fluid to one-fluid and then is flowed into the waste liquid measurement tank 32. Alternatively, a heater may be provided to dry the FOUP 20 instead of the hot blow nozzle. Alternatively, both the hot blow nozzle and the heater may be provided.

Further, the pipe that guides the waste liquid supplied from the first discharge unit 5g to the waste liquid measurement tank 32 via the three-way valve 31 may be provided so that the pipe extends close to the bottom surface of the waste liquid measurement tank 32, which is similar to the pipe that guides the pure water supplied via the first AO valve 33. By supplying the waste liquid to the vicinity of the bottom surface of the waste liquid measurement tank 32, it is possible to prevent the formation of foam when the waste liquid is newly supplied to the liquid surface of the waste liquid already reserved in the waste liquid measurement tank 32. By preventing the foaming of the liquid surface, an accurate measurement may be achieved by the liquid level sensor 39, and it is possible to prevent the inclusion of air bubbles in the waste liquid delivered to the particle counter 38.

Further, the waste liquid discharged from the first discharge unit 5g may flow directly to the particle counter 38 without providing the waste liquid measurement tank 32.

Moreover, a portion of the cleaning liquid supplied to the storage space of the shell 20a may flow into the second discharge unit 5h. Only the liquid supplied to the storage space of the shell 20a may be subject to particle measurement.

In addition, the case where the shell 20a and the door 20b are cleaned simultaneously in one cleaning tank 5 has been described, but two cleaning tanks may be provided, one for cleaning the shell 20a and the other for cleaning the door 20b.

Furthermore, the above-described embodiment exemplifies the case where the particle counter 38 is provided in the flow channel connected to the side surface of the waste liquid measurement tank 32 to measure the waste liquid in the flow channel, but not limited to this. For example, a tank may be provided downstream of the waste liquid measurement tank 32 and the waste liquid fed from the relevant tank may be measured by the particle counter 38. In this case, it is possible to have the waste liquid measurement tank 32 or the downstream tank in a sealed structure and connect a degassing pump to the tank, allowing the waste liquid in the tank to be degassed before being fed to the particle counter 38.

Further, the above-described embodiment exemplifies the case where pure water, which is the one-fluid liquid supplied from the nozzle 5m, is collected in the waste liquid measurement tank 32 and measured by the particle counter 38, but not limited to this. For example, a dedicated nozzle that supplies a fluid (pure water) to be fed to the particle counter 38 may be provided. Alternatively, it is also possible to provide a nozzle, other than the nozzle (e.g., the nozzle 5m) that ejects the cleaning liquid, for supplying the fluid used for processing the FOUP 20, allowing the fluid fed to the particle counter 38 to be supplied from this nozzle. The fluid from the nozzle may be supplied to cover the region of the shell 20a where a wafer holding shelf (not illustrated) is formed.

From the foregoing, it will be appreciated that various embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A cleaning apparatus comprising:
a cleaning tank body having a body opening and a cleaning space communicating with the body opening, the cleaning tank body being configured to clean a wafer storage container;
a lid provided to be openable and closable with respect to the body opening;
a mounting stage provided in the cleaning space, configured to place a shell of the wafer storage container in a state where a shell opening of the shell faces the mounting stage, and formed with a through hole at a portion that faces the shell opening of the shell to be communicated with a storage space of the shell for storing a semiconductor wafer;
a first ejector configured to eject a cleaning liquid into the storage space of the shell;
a second ejector configured to eject the cleaning liquid into an outer portion of the shell;
a first discharge port communicating with the through hole of the mounting stage and configured to discharge the cleaning liquid ejected into the storage space of the shell;
a second discharge port configured to discharge the cleaning liquid that has passed through the outer portion of the shell; and
a particle counter configured to measure particles in the cleaning liquid discharged by the first discharge port.

2. The cleaning apparatus according to claim 1, wherein the lid has a holder configured to hold a door of the wafer storage container attached to be openable and closable with respect to the shell opening of the shell, and
the second ejector further ejects the cleaning liquid onto an inner surface of the door.

3. The cleaning apparatus according to claim 1, further comprising:
a controller configured to control the cleaning apparatus such that the wafer storage container is additionally cleaned when a count of the particles measured by the particle counter is equal to or greater than a predetermined value after the wafer storage container is cleaned for a predetermined cleaning time.

4. The cleaning apparatus according to claim 3, wherein the controller determines a cleaning time to be added based on the count of the particles.

5. The cleaning apparatus according to claim 1, further comprising:
a controller configured to control the cleaning apparatus such that cleaning of the wafer storage container is completed when a count of the particles measured by the particle counter is less than a predetermined value.

6. The cleaning apparatus according to claim 1, further comprising:
a controller configured to determine a cleaning time for the wafer storage container based on information on a wafer stored in the wafer storage container.
